(19) United States
(12) Patent Application Publication
(10) Pub. No.: US 2024/0145614 A1
(43) Pub. Date: May 2, 2024

(54) LIGHT EMITTING AND RECEIVING DEVICE

(71) Applicant: Commissariat à I'Énergie Atomique et aux Énergies Alternatives, Paris (FR)

(72) Inventor: Florian Dupont, Grenoble Cedex 9 (FR)

(73) Assignee: Commissariat à I'Énergie Atomique et aux Énergies Alternatives, Paris (FR)

(21) Appl. No.: 18/493,608

(22) Filed: Oct. 24, 2023

(30) Foreign Application Priority Data
Oct. 27, 2022 (FR) 2211189

(51) Int. Cl. H01L 31/12; H01L 25/04; H01L 31/02; H01L 31/0224; H01L 31/0232

(52) U.S. Cl. CPC H01L 31/125; H01L 25/042; H01L 31/02016; H01L 31/022475; H01L 31/02322

(57) ABSTRACT

The present description relates to a light emitting and receiving device including:-a light-emitting diode including a first active layer, a first electrode in contact with the lower face of the first active layer, and a second electrode in contact with the upper face of the first active layer; and opposite the light-emitting diode, on an emission face of the light-emitting diode, a light conversion and detection element comprising a second active layer, a third electrode in contact with the lower face of the second active layer, and a fourth electrode in contact with the upper face of the second active layer.

### CROSS REFERENCE TO RELATED APPLICATIONS

This application claims priority to French application number 221189, filed Oct. 27, 2022, the contents of which is incorporated by reference in its entirety.

### TECHNICAL FIELD

The present description relates to the field of optoelectronic devices in general. More specifically, it covers a light-emitting and light-receiving device.

### BACKGROUND ART

An emissive display device comprising a matrix of light-emitting diodes (LEDs) and a control circuit for individually driving the LEDs to display images has already been proposed.

For certain applications, the device can further comprise an infrared light source and an infrared receiver, coordinated to measure distance information to a scene or object, also known as depth information, for example by measuring time-of-flight or by analyzing deformations of a structured light beam. This makes it possible, for example, to produce an interactive display device in which the images displayed can be adapted as a function of the depth information measured by means of the infrared emitting/receiving device.

For certain applications, it would be desirable to be able to integrate the infrared source and infrared receiver in a distributed way within the LED matrix of the display device.

### SUMMARY OF THE INVENTION

One embodiment provides a light emitting and receiving device comprising:
a light-emitting diode comprising a first active layer, a first electrode in contact with the lower face of the first active layer, and a second electrode in contact with the upper face of the first active layer; and
opposite the light-emitting diode, on an emission face of the light-emitting diode, a light conversion and detection element comprising a second active layer, a third electrode in contact with the lower face of the second active layer, and a fourth electrode in contact with the upper face of the second active layer.

According to an embodiment, the device further comprises an electronic control circuit configured to, during an emission phase, apply a current in the first active layer via the first and second electrodes, and keep the third and fourth electrodes open-circuited, or, during a reception phase, keep the first and second electrodes open-circuited or short-circuited and measure, via the third and fourth electrodes, an electrical signal representative of light radiation absorbed by the second active layer.

According to an embodiment, the second active layer is made of a photoluminescent material adapted to absorb photons in the emission wavelength range of the light-emitting diode, and, in response, to re-emit photons in another wavelength range.

According to an embodiment, the light-emitting diode is adapted to emit visible light, for example blue light, and wherein the second active layer is adapted to emit infrared radiation.

According to an embodiment, the second active layer is made of a perovskite material.

According to an embodiment, the second active layer is made of an inorganic perovskite material.

According to an embodiment, the second active layer is made of CsSnI₃.

According to an embodiment, the second and third electrodes are transparent in the emission wavelength range of the light-emitting diode, and wherein the fourth electrode is transparent in the emission wavelength range of the second active layer.

According to an embodiment, the second and third electrodes are electrically insulated from each other by a passivation layer transparent in the emission wavelength range of the light-emitting diode.

According to an embodiment, the device further comprises, on the upper face of the light conversion and detection element, an optical filter adapted to pass light radiation in the emission wavelength range of the second active layer and to block light radiation in the emission wavelength range of the light-emitting diode.

Another embodiment provides an elementary chip of an optoelectronic device comprising the above defined light-emitting and light-receiving device.

According to an embodiment, the elementary chip further comprises one or more emissive cells each comprising a light-emitting diode.

Another embodiment provides an optoelectronic device comprising a plurality of elementary chips as defined above, fixed and electrically connected to a single interconnection tile.

Another embodiment provides a method of manufacturing the above defined light emitting and receiving device, wherein the perovskite material is deposited by pulsed laser deposition.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 is a schematic cross-sectional view of an example of a light-emitting and light-receiving device;

FIG. 2 is a cross-sectional view illustrating in greater detail an example of the device shown in FIG. 1;

FIG. 3 is a cross-sectional view illustrating in greater detail another example of the device shown in FIG. 1;

FIG. 4 is a cross-sectional view schematically illustrating an example of a pixel in an interactive display device; and

FIG. 5 is a cross-sectional view schematically illustrating another example of a pixel in an interactive display device.

### DESCRIPTION OF EMBODIMENTS

Like features have been designated by like references in the various figures. In particular, the structural and/or functional features that are common among the various embodiments may have the same references and may dispose identical structural, dimensional and material properties.

For the sake of clarity, only those steps and elements that are useful for understanding the described embodiments have been illustrated and are detailed. In particular, the electronic control circuits of the light-emitting and/or light-receiving devices described have not been detailed, the embodiments described being compatible with usual control circuits of light-emitting and/or light-receiving devices, or the realization of such circuits being within the capabilities of the person skilled in the art from the indications of the present description. Furthermore, the processes for manufacturing the light-emitting and/or light-receiving devices described have not been detailed, the embodiments described being compatible with usual processes for manufacturing light-emitting and/or light-receiving devices, or the implementation of these processes being within the capabilities of the person skilled in the art from the indications of the present description.

Unless otherwise specified, when reference is made to two elements being connected to each other, this means directly connected without any intermediate elements other than conductors, and when reference is made to two elements being “coupled” to each other, this means that these two elements may be connected or may be connected via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the figures.

Unless otherwise specified, the expressions “about”, “approximately”, “substantially”, and “of the order of” mean to within 10%, preferably to within 5%.

According to one aspect of the described embodiments, a light-emitting and light-receiving device is provided comprising a light source and a wavelength conversion element superimposed on the light source. When emitting, the light source is activated and the wavelength conversion element converts the light emitted by the light source to another wavelength range called the emission wavelength range of the conversion element. On reception, the light source is deactivated, and the conversion element is electrically connected, via transparent electrodes, to a readout circuit. The conversion element is then used as a photosensitive detector. More specifically, the readout circuit reads an electrical signal representative of a light intensity received by the conversion element in its absorption wavelength range.

Such a device can thus be used either as a light emitter or receiver, in a range of wavelengths determined by the choice of the conversion element. In this way, light sources and detectors, for example infrared, can be integrated into a wide range of devices, such as interactive displays, in a variety of different, possibly reconfigurable, arrangements. Production costs are reduced by using identical components for the emitting and receiving functions (economy of scale).

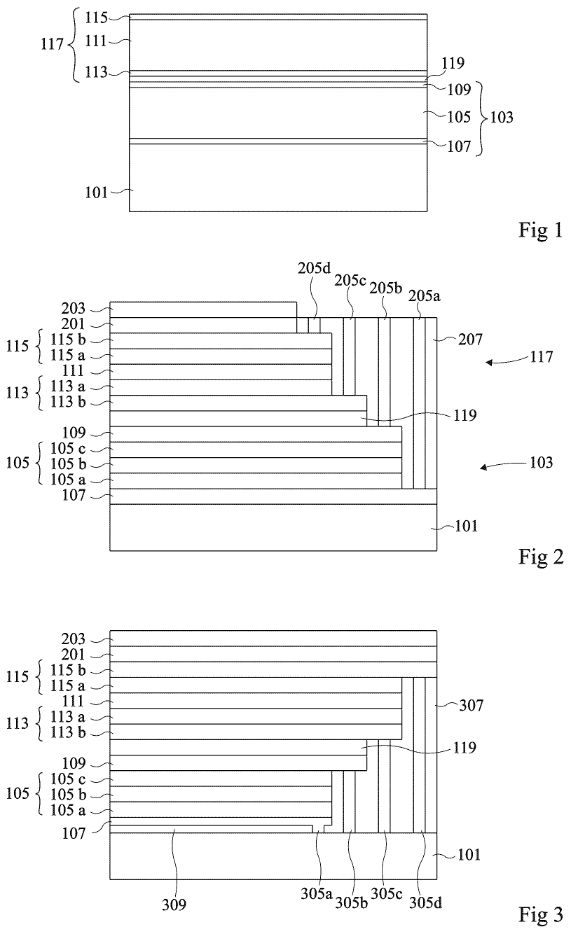

FIG. 1 is a schematic cross-sectional view of an example of a light-emitting and light-receiving device according to one embodiment.

The device shown in FIG. 1 comprises a substrate 101, for example made of silicon, glass, sapphire or any other suitable material.

The device shown in FIG. 1 also comprises, on the upper side of substrate 101, an LED 103 comprising an active layer 105, a lower electrode 107 and an upper electrode 109. The lower electrode 107 is in contact, by its upper side, with the lower side of the active layer 105, and the upper electrode 109 is in contact, by its lower side, with the upper side of the active layer 105. In this example, the lower electrode 107 is in contact, by its lower face, with the upper face of the substrate 101.

The active layer 105 is, for example, an inorganic semiconductor layer or a stack of inorganic semiconductor layers, e.g. based on one or more III-V semiconductor materials, such as gallium nitride. By way of example, LED 103 is adapted to emit predominantly blue light, for example in a wavelength range between 380 and 500 nm.

The device shown in FIG. 1 also includes a photoluminescent wavelength conversion element 111 on the top side of the LED 103. The element 111 is a layer of a semiconductor material adapted to absorb photons in an emission wavelength range of the LED 103, and to re-emit photons in another wavelength range called the emission wavelength range of the conversion element, for example an infrared wavelength range, for example between 780 nm and 3 μm, for example between 800 nm and 1.5 μm.

The device shown in FIG. 1 further comprises an electrode 113 on the underside of the conversion layer 111 and an upper electrode 115 on the top side of the conversion layer 111. The upper side of electrode 113 is in contact with the lower side of conversion layer 111, and the lower side of electrode 115 is in contact with the upper side of conversion layer 111.

The electrodes 113 and 115 and the conversion layer 111 define a photodetector 117 adapted to convert a light signal received in a wavelength range characteristic of the conversion layer 111 into an electrical signal.

In the example shown in FIG. 1, the lower electrode 113 of the photodetector 117 is electrically insulated from the upper electrode 109 of the LED 103 by an insulating layer 119. In the example shown, the insulating layer 119 is in contact, by its lower face, with the upper face of electrode 109, and, by its upper face, with the lower face of electrode 113.

In the emission phase, LED 103 is activated. To do this, a current is injected into its active layer 105 via electrodes 107 and 109. As a result, photons are emitted by the LED's active layer 105.

The photons emitted by LED 103 are absorbed by conversion layer 111, which in response emits photons in the emission wavelength range of layer 111.

During the emission phase, electrodes 113 and 115 are kept open-circuited, unpolarized. For example, electrodes 113 and 115 are left floating. This ensures that the electrical charges photogenerated in layer 111 during absorption of the photons emitted by LED 103 are not evacuated, and that photons are re-emitted by layer 111 in its emission wavelength range.

In the receiving phase, LED 103 is deactivated, i.e. no current is injected into its active layer 105, which then emits no photons. For example, LED electrodes 107 and 109 are left open-circuited or short-circuited.

The photodetector's electrodes 113 and 115 are in turn connected to a readout circuit adapted to measure an electrical signal representative of light radiation absorbed by the conversion layer 111 in its absorption wavelength range. By way of example, the readout circuit is adapted to measure a photo-current flowing between electrodes 113 and 115 under the effect of incident light radiation.

The design of the electronic control circuit of the device, adapted, in the emission phase, to activate the LED to emit light and to maintain the electrodes 113 and 115 of the photodetector 117 in open circuit, and, in the reception phase, to deactivate the LED and to measure, via the electrodes 113 and 115, an electrical signal representative of the incident light radiation, has not been detailed, the design of such a circuit being within the capabilities of the person skilled in the art from the functional indications of the present description.

In the example shown in FIG. 1, the device is adapted to emit and receive light via its top face.

The lower electrode 107 preferably comprises at least one layer reflecting in the emission wavelength range of the LED 103, for example a metal layer, e.g. aluminum.

The top electrode 109 is preferably transparent to the emission wavelength of the LED 103. For example, top electrode 109 is made of a transparent conductive oxide, such as indium tin oxide (ITO).

The electrically insulating layer 119 is preferably transparent in the emission wavelength range of the LED 103. By way of example, layer 119 is silicon oxide (SiO₂).

The lower electrode 113 of photodetector 117 is preferably transparent in the emission wavelength range of LED 103. By way of example, electrode 113 comprises a stack of one or more layers of one or more transparent conductive oxides.

The top electrode 115 of photodetector 117 is preferably transparent in the emission wavelength range of conversion layer 111. By way of example, electrode 115 comprises a stack of one or more layers of one or more transparent conductive oxides.

Preferably, the photoluminescent conversion layer 111 is made of a material with a perovskite structure, also known as perovskite material.

One advantage is that perovskite materials have high internal quantum efficiencies of up to 100%.

Another advantage is that perovskite materials have a high absorption coefficient. In this way, the light conversion function and the photodetection function can be efficiently performed by a relatively thin layer, for example one with a thickness of less than 1 μm, for example in the range from 200 to 500 nm.

Another advantage is that perovskite materials can be deposited at relatively low temperatures, e.g. below 400° C., enabling them to be deposited on top of a CMOS (Complementary Metal Oxide Semiconductor) integrated circuit.

Layer 111, for example, is deposited by PLD (Pulsed Laser Deposition). PLD involves sputtering or ablating a target of perovskite material using a pulsed laser, so as to transfer the material into a plasma and then, via the plasma, onto the target substrate. One advantage of PLD deposition is that it enables the deposition of materials of complex composition such as perovskite materials with good crystalline quality, and this at a relatively low temperature, for example below 400° C. Another advantage of PLD is that these materials can be deposited without damaging the target substrate. Alternatively, the layer 111 can be deposited by any other suitable deposition method. For example, layer 111 can be deposited by liquid deposition, e.g. sol-gel deposition, blade coating, slot-die coating, spray coating or inkjet printing. Alternatively, layer 111 is deposited by solid-state deposition, e.g. by physical vapor deposition, such as evaporation, co-evaporation, spraying or co-spraying.

One or more anneals can be carried out to obtain the desired crystalline phase of the perovskite material.

Another advantage is that perovskite materials are highly tolerant of crystal structure defects. As a result, the light conversion and photodetection functions can be efficiently performed by a relatively thin polycrystalline layer.

Due to the low thicknesses required for the light conversion and photodetection functions, perovskite material layers can be easily etched, enabling conversion and detection elements to be produced with very small lateral dimensions.

As a result, perovskite materials are particularly advantageous for the production of light-emitting and light-receiving devices in small pixels, for example for the production of color image display screens with an inter-pixel pitch of less than 100 μm, for example less than 20 μm, or even less than 5 μm.

The perovskite material used is, for example, an inorganic material. Alternatively, an organic perovskite material can be used.

For example, a perovskite material based on cesium, tin and iodine, such as CsSnI₃, can be used to emit and receive infrared light. More generally, any perovskite material with a bandgap at the desired operating wavelength can be used.

In general, halogen perovskite materials are preferred, i.e. of the type ABX₃, where:
A is an inorganic element (referred to as an inorganic halogen perovskite material), e.g. cesium (Cs), rubidium (Rb), phosphorus (K) or lithium (Li), or an organic element (this is referred to as an organic halogen perovskite material), for example formadiminium, also known as FA, with the chemical formula CN₂H₅₊, or methylammonium, also known as MA, with the chemical formula CH₃NH₃₊, or a combination of these elements,
B is, for example, lead (Pb), tin (Sn) or germanium (Ge), or a combination of these elements, and
X is a halogen, for example bromine (Br), chlorine (Cl), iodine (I) or a combination of halogens.

However, the described embodiments are not limited to these particular perovskite material structures.

Alternatively, halogenated structures of the type, ABX₃ or A₂BX₄ or A BX₃₅ or A₄BX₆ can be used, where B is included in the list comprising lead (Pb), tin (Sn), germanium (Ge), optionally copper, iron or palladium.

Alternatively, halogenated structures of the type, A₃B₂X₉ can be used, where B is included in the list comprising bismuth (Bi) and antimony (Sb).

Alternatively, halogenated structures of the type, A BX₂₆ can be used, where B is included in the list comprising tin, palladium and titanium.

More generally, any other suitable perovskite material structure can be used.

FIG. 2 is a cross-sectional view showing a more detailed example of the device shown in FIG. 1.

In this example, the active layer 105 of the LED 103 comprises, in order from the upper face of the lower electrode 107, a first semiconductor layer 105a doped with a first conductivity type, for example N-type, a multiple-quantum-well stack (not detailed in the FIG. 105b, and a second semiconductor layer 105c doped with a second conductivity type opposite to the first conductivity type, for example P-type. Layer 105a is, for example, in contact, by its lower face, with the upper face of electrode 107, and, by its upper face, with the lower face of multiple-quantum-well stack 105b. Layer 105c, for example, is in contact with the top face of multiple-quantum-well stack 105b via its bottom face, and with the bottom face of electrode 109 via its top face. Layers 105a and 105b are made, for example, of a III-V semiconductor material, such as gallium nitride. The multiple-quantum-well stack 105b comprises, for example, one or more emissive layers each forming a quantum well, for example based on GaN, InN, InGaN, AlGaN, AN, AlInGaN, GaP, AlGaP, AlInGaP, or a combination of one or more of these materials. Alternatively, the multiple-quantum-well stack 105b can be replaced by a layer of intrinsic, i.e. unintentionally doped, gallium nitride, for example with a residual donor concentration of between 10\hat{ }15 and 10\hat{ }19 atoms/cm3, for example of the order of 10\hat{ }17 atoms/cm3.

In the example shown in FIG. 2, the lower electrode 113 of photodetector 117 comprises a hole-transport layer 113a with its upper side in contact with the lower side of conversion layer 111, and a conductive layer 113b with its upper side in contact with the lower side of layer 113a and with its lower side in contact with the upper side of passivation layer 119.

In the example shown in FIG. 2, the upper electrode 115 of the photodetector 117 comprises an electron transport layer 115a in contact, by its lower face, with the upper face of the conversion layer 111, and a conductive layer 115b in contact, by its lower face, with the upper face of the layer 115a.

If the conversion layer 111 is made of a perovskite material, e.g. CsSnI₃, the hole-transport layer 113a is made of nickel oxide (NiO), for example, and the electron-transport layer 115a is made of titanium dioxide (TiO₂) or tin dioxide (SnO₂), for example. Conductive layers 113b and 115b are made of a transparent conductive oxide, such as ITO. Alternatively, the hole transport layer can be made of an organic material, such as Spiro-OMeTAD or BCP (Bathocuproin). The electron-transport layer can be made of an organic material, such as PCBM ([6,6]-phenyl-C₆₁-methylbutanoate).

By way of example, the device may further comprise a top passivation layer 201 arranged on and in contact with the top face of electrode 115, i.e. on and in contact with the top face of conductive layer 115b in the example shown. The passivation layer 201 is preferably transparent in the emission wavelength range of the conversion layer 111. By way of example, the top passivation layer 201 is made of silicon oxide (SiO₂).

By way of example, the device may further comprise an optical filter 203 arranged above the photodetector 117, for example on and in contact with the top face of the passivation layer 201. The optical filter is, for example, a bandpass or high-pass filter adapted to let light pass in the emission wavelength range of the conversion layer 111, and to block light at other wavelengths and in particular in the emission range of the LED 103. By way of example, optical filter 203 is adapted to pass infrared radiation and block visible radiation.

For example, optical filter 203 allows:
on emission, to prevent residual rays emitted by LED 103 and not converted by conversion layer 111 from being extracted from the device and projected towards the user; and/or
on reception, to block incident radiation outside the wavelength range of interest being measured, thereby improving the selectivity of photodetector 117.

The optical filter 203 is, for example, a resin filter or an interference filter, for example made up of alternating dielectric layers with different refractive indices.

In the example shown in FIG. 2, four conductive vias 205a, 20a5b, 205c, 205d are schematically shown in contact, by their lower faces, with the upper face of electrode 107, the upper face of electrode 109, the upper face of the conductive layer 113b of electrode 113, and the upper face of electrode 115b, respectively. The conductive vias 205a, 205b, 205c, 205d are, for example, metallic. In the example shown, the conductive vias 205a, 205b, 205c, 205d are laterally surrounded by an insulating material 207, for example silicon oxide.

The conductive vias 205a, 205b, 205c, 205d allow, in this example, the contacts on electrodes 107, 109, 113 and 115 to be returned to the upper side of the device. The electrodes 107, 109, 113 and 115 can thus be connected, via the conductive vias 205a, 205b, 205c, 205d, to a control circuit configured to control the device in emission, in reception, or alternately in emission and in reception.

FIG. 3 is a cross-sectional view illustrating in greater detail another example of the device shown in FIG. 1.

The example in FIG. 3 differs from that in FIG. 2 mainly in that, in the example in FIG. 3, the conductive vias 205a, 205b, 205c and 205c of the example in FIG. 2 are replaced by four conductive vias 305a, 305b, 305c, 305d in contact, by their upper faces, with respectively the lower face of electrode 107, the lower face of electrode 109, the lower face of electrode 113, and the lower face of the conductive layer 115b of electrode 115. Conductive vias 305a, 305b, 305c, 305d are, for example, metallic. In the example shown, the conductive vias 305a, 30a5b, 305c, 305d are laterally surrounded by an insulating material 207, for example silicon oxide. In this example, the lower electrode 107 of the LED 103 is separated from the substrate 101 by an electrically insulating layer 309, for example of silicon oxide.

In this example, the conductive vias 305a, 305b, 305c, 305d bring the contacts on the electrodes 107, 109, 113 and 115 back to the upper side of the substrate. By way of example, the conductive vias 305a, 305b, 305c, 305d are respectively in contact, via their lower faces, with metal connection pads (not detailed in the figures) located on the upper face side of the substrate 101.

The 101 substrate includes, for example, an electronic control circuit, for example based on MOS transistors, such as a CMOS circuit, adapted to control the device in emission, in reception, or alternatively in emission and reception.

A light emitting and receiving device of the type described in relation to FIGS. 1, 2 and 3 can advantageously be integrated into numerous devices, for example into an emissive LED display screen so as to realize an interactive display device. In this case, the device can comprise a plurality of elementary infrared light emitting-receiving cells of the type described in relation to FIGS. 1 to 3, evenly distributed within the pixel matrix of the display device.

By way of example, each pixel of the display device may comprise a plurality of individually controllable LED emissive cells adapted to emit respectively visible light in different wavelength ranges, for example a first cell adapted to emit predominantly red light, a second cell adapted to emit predominantly green light, and a third cell adapted to emit predominantly blue light. Each pixel may further comprise an infrared light emitting-receiving cell of the type described in relation to FIGS. 1 to 3.

The elementary infrared light emission-reception cells can be individually controlled. For example, some cells are controlled to emit light and define an infrared light source distributed within the pixel matrix, and some cells are controlled to receive light and form an infrared sensor distributed within the pixel matrix.

For example, the configuration of elementary cells to emit or receive light can be dynamically modified to adapt to different usage situations of the device.

Alternatively, the configuration of the elementary emitting and receiving cells remains fixed for a given display device. One advantage of the proposed solution is that the emitting and receiving cells are structurally identical, which keeps manufacturing costs down and enables different applications to be addressed with the same device, by modifying only the configuration of the electronic circuit controlling the elementary emitting-receiving cells.

The interactive emissive display device is, for example, a monolithic device, in which all the pixels and their control circuits are monolithically integrated in a single integrated circuit chip. Alternatively, the interactive emissive display device comprises a plurality of discrete microchips attached and electrically connected to a single interconnect tile. By way of example, each microchip corresponds to a pixel of the display device and comprises, for example, three LED emissive cells adapted to emit red light, green light and blue light respectively, and an infrared light emission-reception cell.

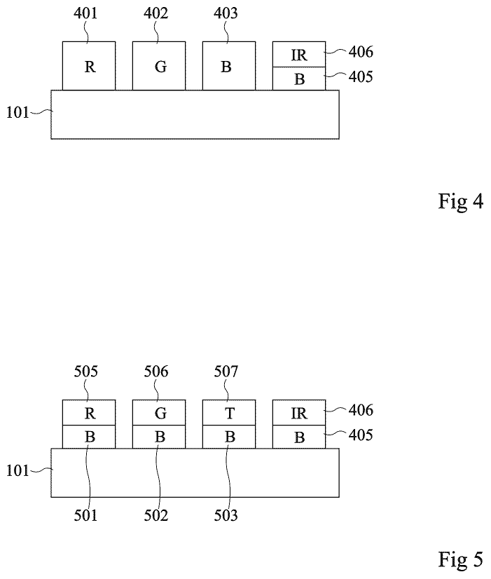

FIG. 4 schematically illustrates an example of such a pixel microchip.

In the example shown in FIG. 1, the pixel microchip comprises, on a single substrate 101, three LEDs 401, 402, 403 adapted to emit red light (R), green light (G) and blue light (B) respectively.

The microchip further comprises an infrared light emission-reception cell of the type described in relation to FIGS. 1 to 3, comprising, in this example, an LED 405 adapted to emit blue light (B), and, superimposed on the LED 405, an element 406 adapted, on emission, to convert the light emitted by the LED 405 into infrared radiation (IR) and, on reception, to measure the intensity of incident infrared radiation.

The 101 substrate includes, for example, an integrated circuit for controlling the visible LEDs 401, 402, 403 and the infrared light emission-reception cell 405, 406. The control circuit is based on CMOS technology, for example.

For each microchip, the transfer plate comprises, for example, metal connection pads intended, during transfer, to be electrically connected to corresponding metal connection pads on the microchip, for example arranged on the side of the substrate 101 opposite the LEDs.

FIG. 5 schematically illustrates another example of a pixel microchip of the type described above.

In the example shown in FIG. 5, the pixel microchip comprises, on the same substrate 101, three LEDs 501, 502, 503, for example identical to within manufacturing dispersions, adapted to emit light in the same wavelength range, for example blue light (B).

LED 501 is coated, on its upper face, with a photoluminescent conversion element 505 adapted to convert the light emitted by LED 501 into visible light at another wavelength, for example red light (R).

The LED 502 is coated, on its upper face, with a photoluminescent conversion element 506 adapted to convert the light emitted by the LED 502 into visible light at another wavelength, different from the emission wavelength of the conversion element 505, for example green light (G).

The top side of LED 503 is coated with a layer 507 that is transparent (T) to the emission wavelength of LED 503.

Thus, in this example, the LED 501 and the conversion element 505 define a first emissive cell adapted to emit predominantly red light, the LED 502 and the conversion element 506 define a second emissive cell adapted to emit predominantly green light, and the LED 503 and the transparent layer define a third emissive cell adapted to emit predominantly blue light.

Photoluminescent conversion elements 505 and 506 are made of perovskite materials, for example. In this example, the photoluminescent conversion elements 505 and 506 are not electrically contacted.

The microchip further comprises, as in the example of FIG. 4, an infrared light emission-reception cell of the type described in relation to FIGS. 1 to 3, comprising, in this example, an LED 405 adapted to emit blue light (B), and, superimposed on the LED 405, an element 406 adapted, on emission, to convert the light emitted by the LED 405 into infrared radiation (IR) and, on reception, to measure the intensity of incident infrared radiation.

Substrate 101 includes, for example, an integrated circuit for controlling the visible LEDs 501, 502, 503 and the infrared light emission-reception cell 405, 406. The control circuit is based on CMOS technology, for example.

Note that in the examples shown in FIGS. 4 and 5, each pixel microchip comprises three LED visible light emission cells and one infrared light emission-reception cell, arranged on a single support substrate incorporating a control circuit for said cells.

Alternatively, each pixel can comprise several discrete microchips, for example four microchips, for example a first microchip comprising only the red light emission cell 401/501-505 and its control circuit, a second microchip comprising only the green light emission cell 402/502-506 and its control circuit, a third microchip comprising only the blue light emission cell 403/503-507 and its control circuit, and a fourth microchip comprising only the infrared light emission-reception cell 405-506 and its control circuit, a third microchip comprising only the blue light emission cell 403/503-507 and its control circuit, and a fourth microchip comprising only the infrared light emission-reception cell 405-506 and its control circuit. In other words, in the examples shown in FIGS. 4 and 5, the four cells can be singularized by cutting the substrate 101 between the cells.

In another variant, the various cells for visible light emission and infrared light emission-reception can be implemented in the form of elementary microchips that do not incorporate control circuitry. In such cases, the microchips can be mounted on an interconnection plate incorporating selection transistors made, for example, using TFT (Thin Film Transistor) technology. For each chip, the transfer plate comprises metal connection pads designed, during transfer, to be electrically connected to the LED electrodes and, in the case of emitting-receiving cells, to the electrodes of the cell's photodetector.

Various embodiments and variants have been described. The person skilled in the art will understand that certain features of these various embodiments and variants could be combined, and other variants will become apparent to the person skilled in the art. In particular, although examples of embodiments have been described above in which the light emitting/receiving cell is adapted to emit and detect predominantly infrared light, the embodiments described are not limited to this particular case. Alternatively, the conversion element 111 can be chosen to emit and receive light in another wavelength range, such as visible light.

Furthermore, the embodiments described are not limited to the examples described above in which the transceiver cells are integrated in a distributed manner into an emissive LED display device. Alternatively, the transceiver cells described can be integrated into other types of display devices, for example LCD devices, or more generally, into any type of optoelectronic device, for example fingerprint sensors or any other type of sensor based on the emission and reception of light radiation.

Furthermore, although perovskite materials are particularly advantageous for implementing the wavelength conversion and photodetection functions of the conversion layer 111, the embodiments described are not limited to these materials. More generally, the conversion layer 111 can be made of any other direct-gap semiconductor material with a bandgap at the desired operating wavelength. For example, the conversion layer 111 may comprise quantum dots embedded in a layer or matrix of polymer material.

Furthermore, the embodiments described are not limited to the examples of materials and dimensions mentioned in the description, in particular for the realization of the LEDs of the emitting-receiving cells described.

Finally, the practical implementation of the described embodiments and variants is within the capabilities of the person skilled in the art on the basis of the functional indications given above, in particular with regard to the realization of the electronic control circuits of the emitting-receiving cells described.

1. Light emitting and receiving device comprising:
a light-emitting diode comprising a first active layer, a first electrode in contact with the lower face of the first active layer, and a second electrode in contact with the upper face of the first active layer; and
opposite the light-emitting diode, on an emission face of the light-emitting diode, a light conversion and detection element comprising a second active layer, a third electrode in contact with the lower face of the second active layer, and a fourth electrode in contact with the upper face of the second active layer.

2. The device of claim 1, further comprising an electronic control circuit configured to, during an emission phase, apply a current in the first active layer via the first and second electrodes, and keep the third and fourth electrodes open-circuited, or, during a reception phase, keep the first and second electrodes open-circuited or short-circuited and measure, via the third and fourth electrodes, an electrical signal representative of light radiation absorbed by the second active layer.

3. The device of claim 1, wherein the second active layer is made of a photoluminescent material adapted to absorb photons in the emission wavelength range of the light-emitting diode, and, in response, to re-emit photons in another wavelength range.

4. The device of claim 3, wherein the light-emitting diode is adapted to emit visible light, for example blue light, and wherein the second active layer is adapted to emit infrared radiation.

5. The device of claim 1, wherein the second active layer is made of a perovskite material.

6. The device of claim 5, wherein the second active layer is made of an inorganic perovskite material.

7. The device of claim 5, wherein the second active layer is made of CsSnI₃.

8. The device of claim 1, wherein the second and third electrodes are transparent in the emission wavelength range of the light-emitting diode, and wherein the fourth electrode is transparent in the emission wavelength range of the second active layer.

9. The device of claim 1, wherein the second and third electrodes are electrically insulated from each other by a passivation layer transparent in the emission wavelength range of the light-emitting diode.

10. The device of claim 1, further comprising, on the upper face of the light conversion and detection element, an optical filter adapted to pass light radiation in the emission wavelength range of the second active layer and to block light radiation in the emission wavelength range of the light-emitting diode.

11. Elementary chip of an optoelectronic device comprising a light-emitting and light-receiving device according to claim 1.

12. The elementary chip of claim 11, further comprising one or more emissive cells each comprising a light-emitting diode.

13. Optoelectronic device comprising a plurality of elementary chips according to claim 11 fixed and electrically connected to a single interconnection tile.

14. A method of manufacturing a device according to claim 5, wherein the perovskite material is deposited by pulsed laser deposition.
